(19) United States
(12) Patent Application Publication
(10) Pub. No.: US 2021/0036165 A1
(43) Pub. Date: Feb. 4, 2021

(54) MERGED PiN SCHOTTKY (MPS) DIODE WITH ENHANCED SURGE CURRENT CAPACITY

(71) Applicants: Xiaotian Yu, LOS ANGELES, CA (US); Zheng Zuo, LOS ANGELES, CA (US); Ruigang Li, LOS ANGELES, CA (US)

(72) Inventors: Xiaotian Yu, LOS ANGELES, CA (US); Zheng Zuo, LOS ANGELES, CA (US); Ruigang Li, LOS ANGELES, CA (US)

(73) Assignee: AZ Power, Inc, CULVER CITY, CA (US)

(21) Appl. No.: 16/945,812

(22) Filed: Aug. 1, 2020

Related U.S. Application Data
(60) Provisional application No. 62/881,504, filed on Aug. 1, 2019.

(51) Int. Cl. H01L 29/872; H01L 29/868

(52) U.S. Cl. CPC H01L 29/872; H01L 29/868

(57) ABSTRACT

In one aspect, a merged PiN Schottky (MPS) diode may include a silicon carbide substrate having a first conductivity type. The epitaxial layer with a first conductivity type was formed on the substrate, which has doping concentration lower than the substrate. A plurality of regions having the second conductivity type different from the first conductivity type are formed under the surface of the epitaxial layer. The Ohmic contact metal is formed on the region of the second conductivity type. The Schottky contact metal is placed on top of the entire epitaxial layer to form a Schottky junction. The Ohmic contact was formed by a cathode electrode on the back side of the substrate.

### CROSS-REFERENCE TO RELATED APPLICATIONS

This application claims priority under 35 U.S.C. § 119 (e) to U.S. Provisional Patent Application Ser. No. 62/881,504, filed on Aug. 1, 2019, the entire contents of which are hereby incorporated by reference.

### FIELD OF THE INVENTION

The present invention relates to a power diode structure, and more particularly to a merged PiN junction Schottky (MPS) diode with enhanced reliability under a surge current.

### BACKGROUND OF THE INVENTION

Power devices include power diodes and power switching transistors. Power diodes have two modes of operation in circuit applications, which are conduction mode and blocking mode. For the conduction mode, in addition to nominal current conditions, there is an occasional surge current condition. Under the abnormal conditions with surge current, the diode may have instant energy overshoot and chip temperature rise, resulting in device failure.

Furthermore, power devices are expected to endure high current stresses under surges caused by circuit failure or lightning. Usually a great amount of energy, caused by high current multiplied by high voltage drop, flows into the device in quite a short time, leading to rapidly raised temperature and possibly a device failure. Surge capability is a key performance index which describes the robustness of power devices under extreme operating conditions. Devices with preeminent surge capability can dissipate such energy efficiently without a failure, thus offering a higher safety margin to the power system.

Silicon carbide semiconductor has two times larger bandgap compared with Silicon semiconductor. With a higher critical electric field, higher thermal conductivity, lower intrinsic carrier concentration, and higher saturation drift velocity, silicon carbide semiconductor has become an ideal candidate for high voltage, high temperature and high-power devices.

There are two technical routes for commercial devices based on silicon carbide power diodes, namely junction barrier Schottky (JBS) diode structure and merged PiN Schottky (MPS) diode structure.

For silicon carbide (SiC) materials, the Junction Barrier Schottky (JBS) diode is widely used. Armed with excellent characteristics of SiC material and characterized by alternatively arranged small P+ regions in N− drift layer, it has received large attention for its low forward voltage drop and low reverse leakage current. Merged PiN Schottky (MPS) diode was proposed based on the JBS diode structure, with merged large P+ regions into the active region. PN junctions formed by these large P+ regions will turn on under high current flows. Large amount of minority carriers will be injected into the drift layer, providing a lower resistivity and a higher current conduction capability. Thus, it offers higher surge capability compared to traditional JBS diode, as well as preserving a low forward voltage drop and reverse leakage current at the same time.

### SUMMARY OF THE INVENTION

In one aspect, a merged PiN Schottky (MPS) diode may include a silicon carbide substrate having a first conductivity type, an epitaxial layer with the first conductivity type formed on the substrate, In one embodiment, the doping concentration in the epitaxial layer is lower than that in the substrate. The merged PiN Schottky (MPS) diode may further include a plurality of regions having a second conductivity type different from the first conductivity type, and formed under a top surface of the epitaxial layer.

A first Ohmic contact metal is formed on top of each of the regions of the second conductivity type, and a Schottky contact metal is placed on top of the entire epitaxial layer to form a Schottky junction. A second Ohmic contact is formed by a cathode electrode on the back side of the substrate.

In one embodiment, a merged PiN Schottky (MPS) diode may include narrow P+ region and wide P+ region, where there are four structure design parameters that need to be determined. Namely, the dimensions of the plurality regions with second conductivity type are not uniform, wherein the width (W) of the wide P+ region and its spacing (S), and the width of the narrow P+ region (W₁) and its spacing (S₁) have effects on the electrical performance of the device.

The present invention is to propose a universal design of the merged PiN Schottky (MPS) diode, wherein the width of the wide P+ region (W) and its spacing (S), the width of the narrow P+ region (W₁) and its spacing (S₁) in the device structure design together have a significant impact on the surge current capability of the diode.

### BRIEF DESCRIPTION OF THE DRAWINGS

FIG. 1 is a cross-section view of the merged PiN Schottky (MPS) diode in the present invention.

FIG. 2 shows the relationship between the turn-on voltage of the PN junction (VPN) and surge current capability of the merged PiN Schottky (MPS) diode.

FIG. 3 depicts the I-V curve of 2A 1200V merged PiN Schottky (MPS) diode under nominal current operating condition.

FIG. 4 is the I-V curve of 2A 1200V merged PiN Schottky (MPS) diode under high current operating condition.

FIG. 5 illustrates a partial cross-section view of the merged PiN Schottky (MPS) diode in the present invention.

FIG. 6 illustrates simulation results of the trade-off relationship between nominal current conduction performance and the surge current capability of a 2A 1200V merged PiN Schottky (MPS) diode.

FIG. 7 shows a merged PiN Schottky (MPS) diode layout design with optimized structural parameters in the present invention.

FIG. 8 illustrates the cross-section view of the merged PiN Schottky (MPS) diode with optimized structural parameters along line CC′ in FIG. 7.

FIG. 9 illustrates the cross-section view of the merged PiN Schottky (MPS) diode with optimized structural parameters along line DD′ in FIG. 7.

FIG. 10 illustrates the cross-section view of the merged PiN Schottky (MPS) diode with optimized structural parameters along line EE′ in FIG. 7.

FIG. 11 shows the influence of narrow P+ region design on the leakage current in 2A 1200V merged PiN Schottky (MPS) diode under reverse bias.

FIG. 12 shows the influence of narrow P+ region design on the forward voltage drop of 2A 1200V merged PiN Schottky (MPS) diode.

FIG. 13 illustrates a device layout design with 2 microns of narrow P+ region spacing in the present invention.

FIG. 14 illustrates a device layout design with 4 microns of narrow P+ region spacing in the present invention.

FIG. 15 illustrates a device layout design with 5 microns of narrow P+ region spacing in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

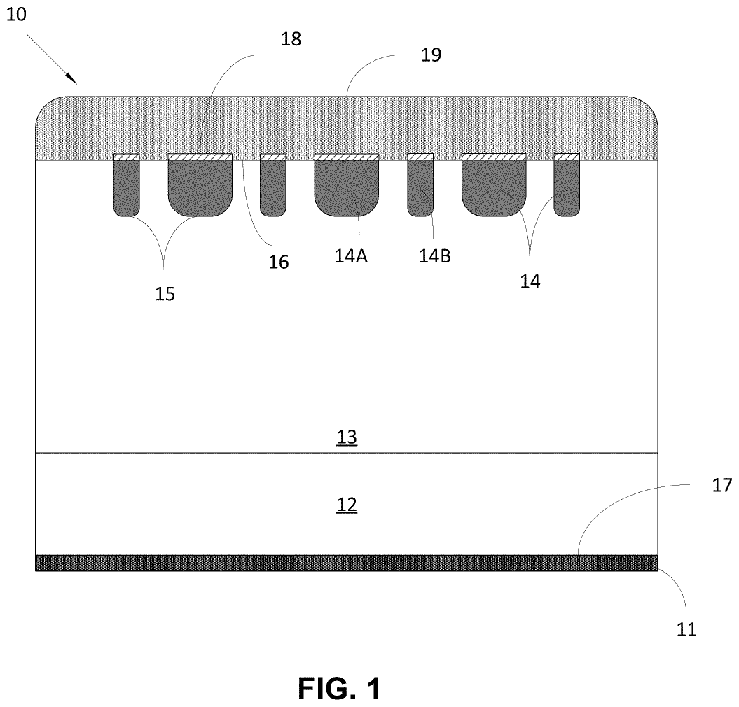

In one aspect as shown in FIG. 1, a merged PiN Schottky (MPS) diode 10 may include a silicon carbide substrate 12 having a first conductivity type, an epitaxial layer 13 with the first conductivity type formed on the substrate 12, In one embodiment, the doping concentration in the epitaxial layer 13 is lower than that in the substrate 12. The merged PiN Schottky (MPS) diode 10 may further include a plurality of regions (14, 14A, 14B) having a second conductivity type different from the first conductivity type, and formed under a top surface of the epitaxial layer 13.

A first Ohmic contact metal 18 is formed on top of each of the regions of the second conductivity type, and a Schottky contact metal 19 is placed on top of the entire epitaxial layer 13 to form a Schottky junction 16. A second Ohmic contact 17 is formed by a cathode electrode 11 on the back side of the substrate 12.

It is noted that in the merged PiN Schottky (MPS) diode structure, a PN junction can be formed by a P+ region (14, 14A, or 14B), and a N-type drift region (15) can be turned on under surge current condition, forming a parallel operation mode between the PN junction and the Schottky junction, providing device with better surge current capability.

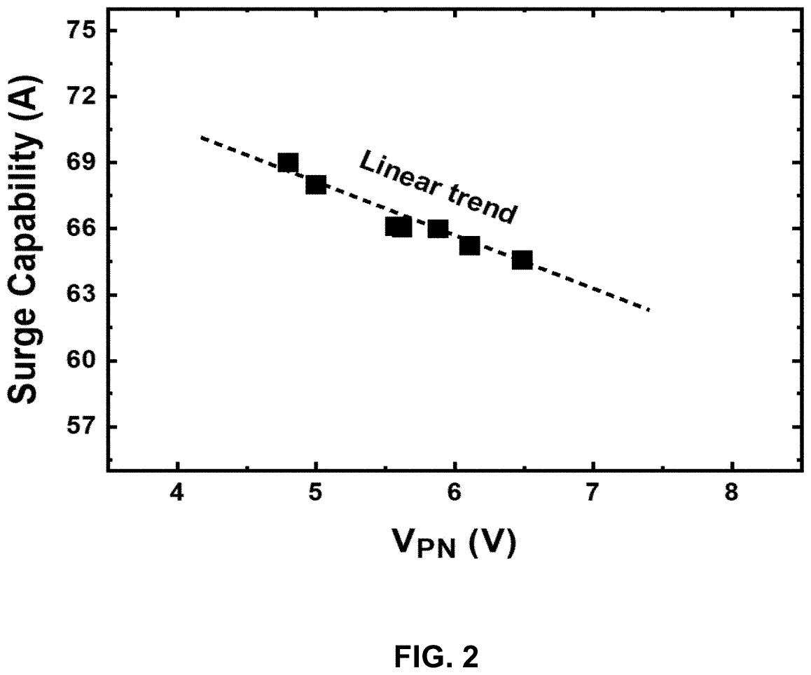

Through different device layout designs and corresponding experimental results, a linear relationship between the turn-on voltage of the PN junction (VPN) and surge current capability is shown in FIG. 2. Therefore, the forward voltage drop (VF) under nominal current conduction condition and the turn-on voltage (VPN) of the PN junction can be used as the key electrical parameters to analyze the nominal current conduction performance and surge current capability of the diode, respectively.

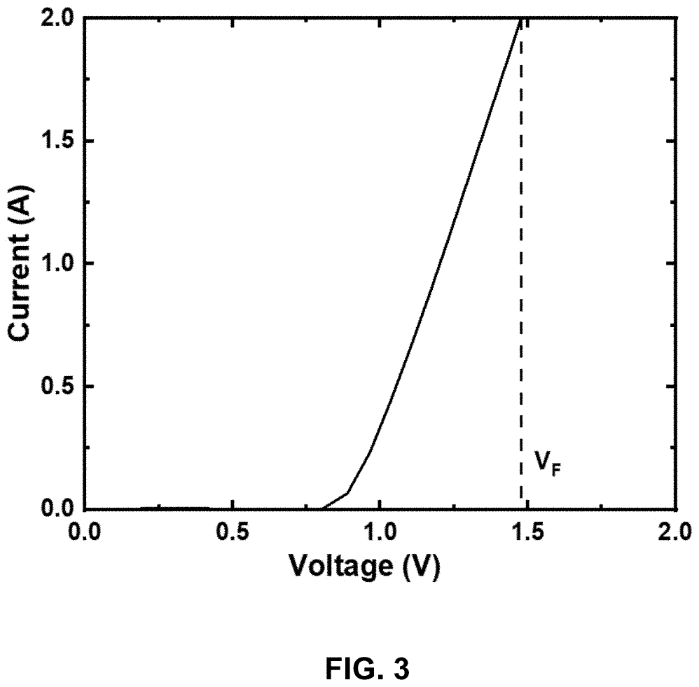

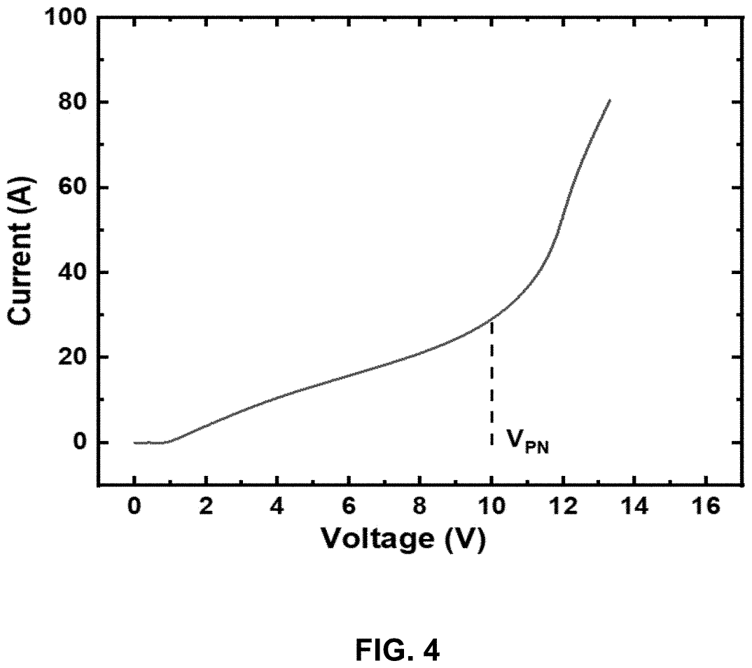

For example, for a 2A 1200V merged PiN Schottky (MPS) diode, the current-voltage (I-V) curves thereof under nominal current operating condition and high current condition are shown in FIGS. 3 and 4, respectively. In FIG. 3, VF is the forward voltage drop when the current of merged PiN Schottky (MPS) diode reaches 2A which is considered the nominal current of the device in FIG. 2. Also, VPN shown in FIG. 4 is the turn-on voltage of the PN junction, which can be used to analyze the surge current capability of the device.

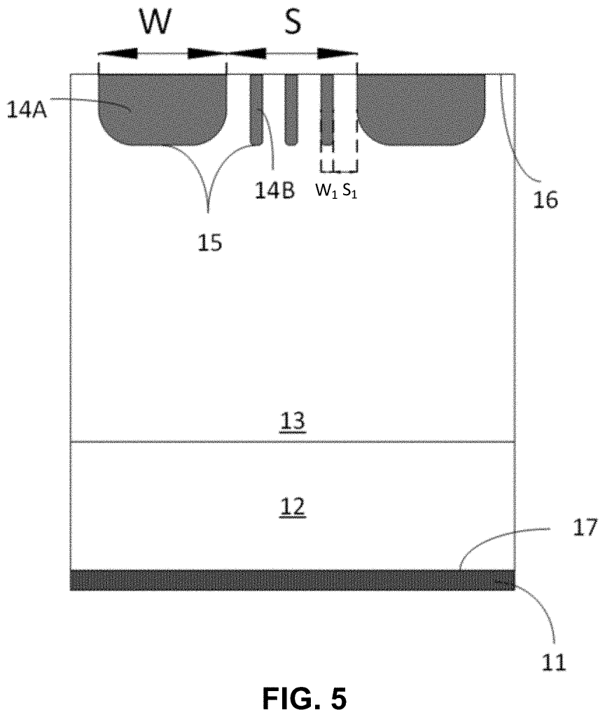

In one embodiment, a merged PiN Schottky (MPS) diode may include narrow P+ region and wide P+ region as shown in the FIG. 5, where there are four structure design parameters that need to be determined. Namely, the dimensions of the plurality regions with second conductivity type are not uniform, wherein the width (W) of the wide P+ region and its spacing (S), and the width of the narrow P+ region (W₁) and its spacing (S₁) have effects on the electrical performance of the device.

The present invention is to propose a universal design of the merged PiN Schottky (MPS) diode. In order to illustrate the concept, the 2A 1200V merged PiN Schottky (MPS) diode with hexagonal cells is taken as an example. The width of the wide P+ region (W) and its spacing (S), the width of the narrow P+ region (W₁) and its spacing (S₁) in the device structure design together have a significant impact on the surge current capability of the diode. The simulation results and experimental results of the device design will be described in detail below.

(1) Structural Parameter Design of wide P+ Region

Still taking the simulation results of 2A 1200V merged PiN Schottky (MPS) diode device as an example, the wide P+ region width (W) and its spacing (S) in the device structure design have obvious influence on the surge current capability. This is because the wide P+ region can be first turned on during the surge current shock, and a large amount of minority carriers are injected into the drift layer, which contributes to lower resistivity and higher current conduction capability, so that the power consumption under the surge current condition can be reduced to improve the device's surge current capability.

For various applications, different sets of requirements will be proposed, such as blocking voltage levels and surge current capabilities, and the structural parameter design of the wide P+ region of the merged PiN Schottky (MPS) diode needs to be adjusted accordingly. For the 2A 1200V merged PiN Schottky (MPS) diode with hexagonal cells design, in one embodiment, the width of the wide P+ region (W) ranges from 2 to 20 microns, and the width of the wide P+ region (S) ranges from 3 to 21 microns.

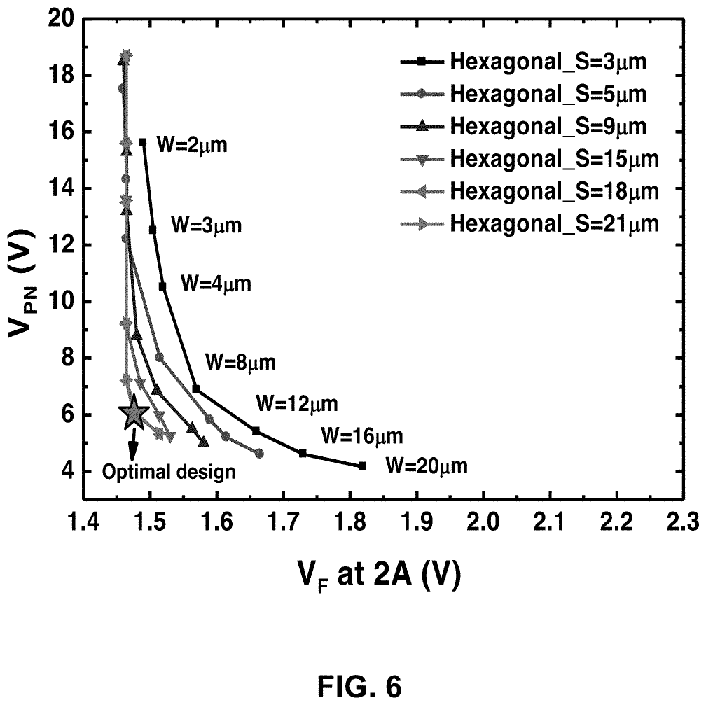

The optimized design parameters for the 2A 1200V merged PiN Schottky (MPS) diode can be determined by the simulation results in FIG. 6. The width of the wide P+ region (W) in the merged PiN Schottky (MPS) diode is around 16 microns while the spacing of the wide P+ region (S) is around 16.5 microns. This optimized design can achieve a lower nominal current forward voltage drop VF and a lower PN junction turn-on voltage VPN, and more importantly a lower PN junction turn-on voltage will provide the device with a better surge current capability (as shown in FIG. 2 above).

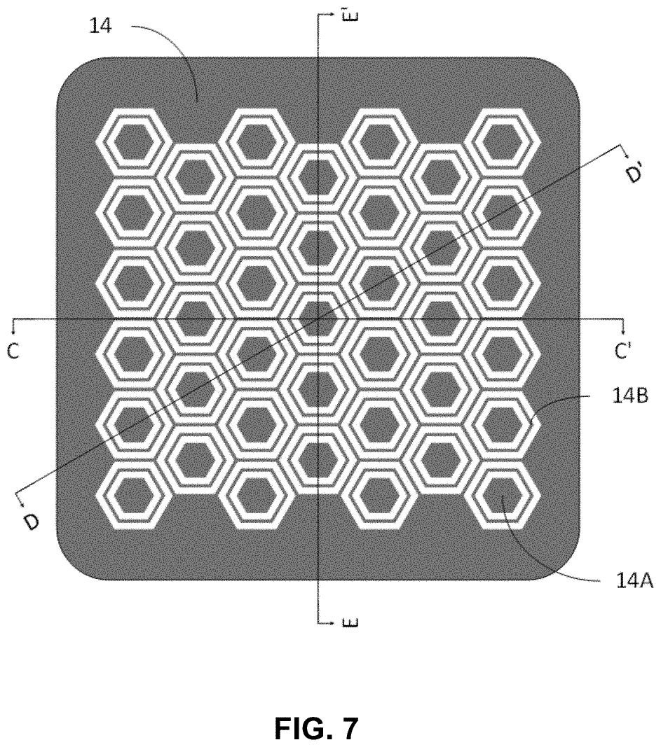

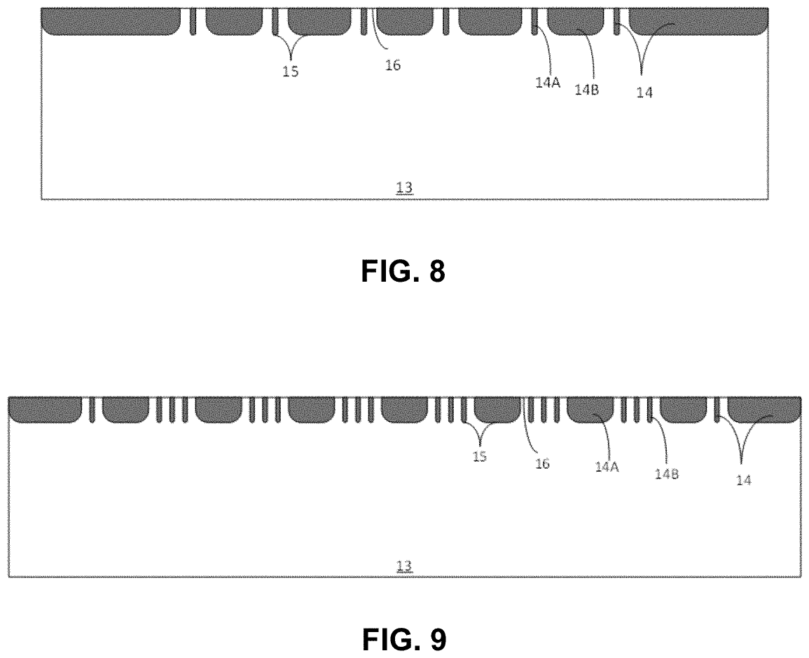

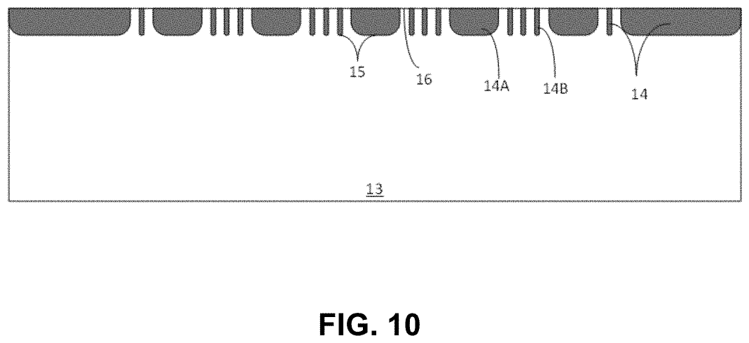

At the same time, narrow P+ regions are evenly distributed between the wide P+ regions, resulting in the device layout design shown in FIG. 7. The structural parameters are designed with wide P+ region width (W) of 16 micrometers and spacing (S) of 16.5 micrometers, while each of three narrow P+ regions with 1.5 microns width is evenly distributed between the adjacent wide P+ regions. FIGS. 8 to 10 are cross-section views of the merged PiN Schottky (MPS) diode with optimized design in FIG. 7 along lines CC′, DD′ and EE′, respectively.

### (2) Structural Parameter Design of Narrow P+ Region

In another embodiment of the merged PiN Schottky (MPS) diode in the present invention, in addition to the width and spacing of the wide P+ region, the width and spacing of the narrow P+ region also affects the electrical performance of the device.

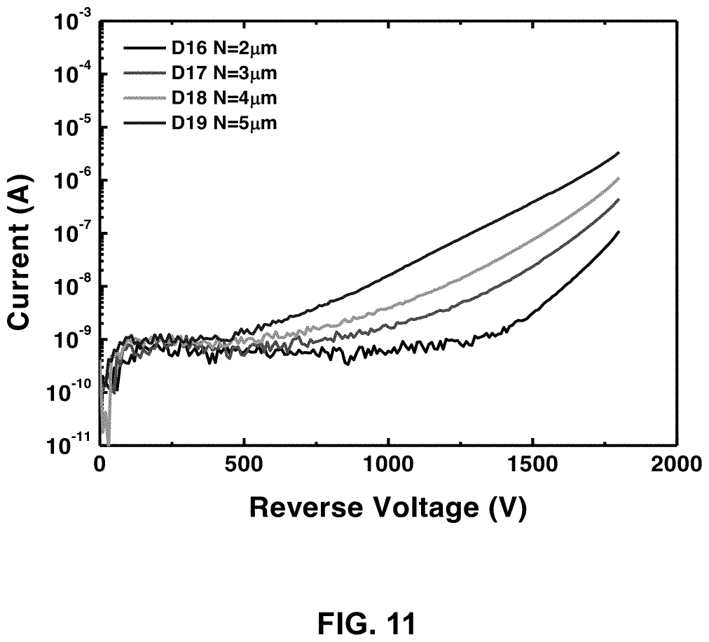

Again, taking a 2A 1200V merged PiN Schottky (MPS) diode as an example, FIG. 11 is the experimental result of the I-V curve of the diode in the reverse blocking mode. The influence of the structural parameter design of the narrow P+ region on the leakage current of the merged PiN Schottky (MPS) diode is that when the width of the narrow P+ region remain constant, as the spacing of the narrow P+ region increases, the reverse leakage current of the diode also increase. Specifically, when the spacing increases from 2 microns to 5 microns, the leakage current level at 1200V increases by two orders of magnitude. This is because the narrow P+ region contribute to the so-called electric field shielding effect. Namely, the PN junction formed between the narrow P+ region and the N-type drift region is located below the Schottky junction and the depletion regions formed by the PN junction under the reverse bias will connect and form a second potential barrier layer. With the second potential barrier layer, the maximum electric field will be relocated from the Schottky junction to the bulk of the N− drift layer. Therefore, the electric field at the Schottky junction will be reduced and the reverse leakage current can be lowered.

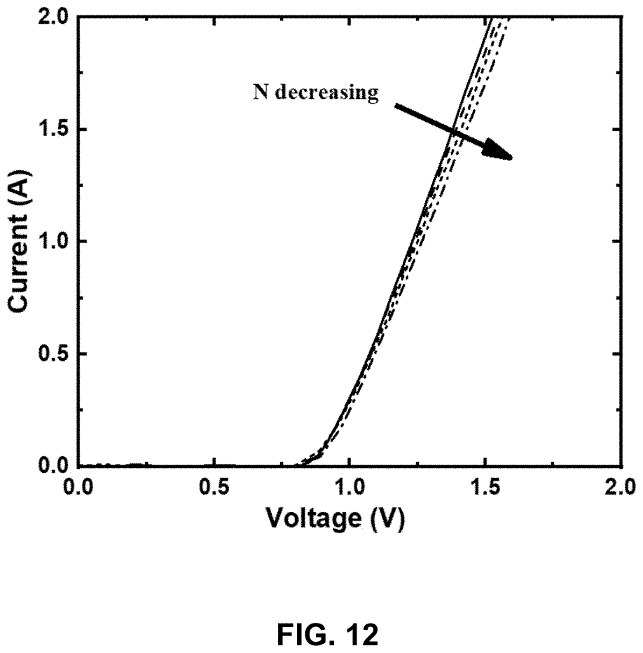

Similarly, the narrow P+ structure parameter design also has an impact on the forward conduction performance of the device. As shown in FIG. 12, the experimental results of the I-V curves of the diode under the forward conduction mode. It can be seen from the figure that the influence of the structural parameter design of the narrow P+ region on the forward voltage drop of the merged PiN Schottky (MPS) diode is: when the width of the narrow P+ region remain constant, as the spacing of the narrow P+ region increases, the forward voltage of the diode decreases.

It is important to note that the design of the narrow P+ region structure parameters will affect the forward voltage drop and reverse blocking leakage current of the device, and there is a trade-off relationship between these two electrical performance indexes. There are different application requirements, such as different blocking voltage level for various bus line voltage design in the circuit, and the limit of power loss in the off mode which determines the leakage current level of the device. After satisfying the application requirements above, increasing the spacing of the P+ region (or reducing the width of the narrow P+ region) can reduce the forward voltage drop of the device to improve the forward conduction performance of the device, and further reduce the chip area and the device cost.

It is also important to note that although a 2A 1200V device is used as examples, the design methodology and idea for the wide P+ region and narrow P+ region structural parameters in the merged PiN Schottky (MPS) diode structure can be generally applied to the design of devices with various current/voltage ratings.

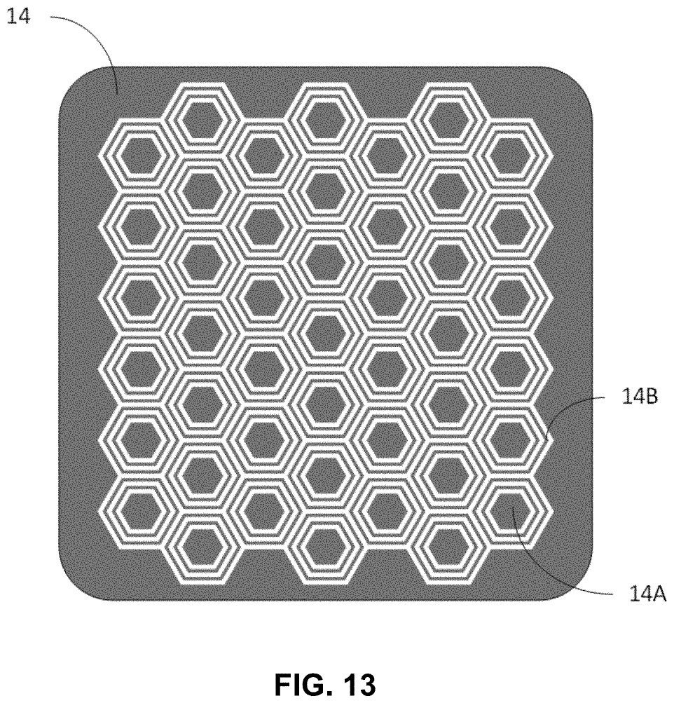

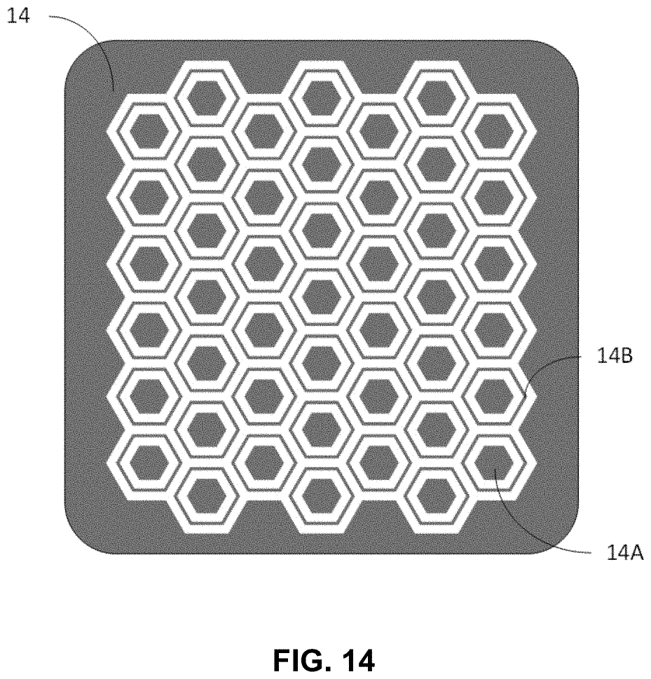

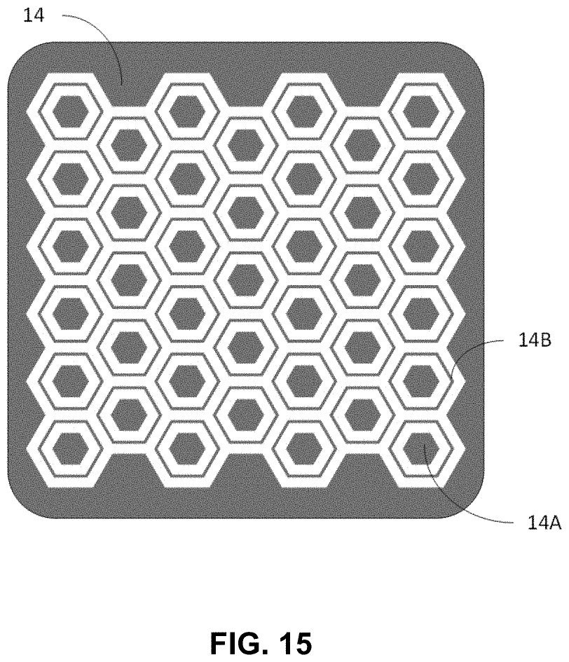

In the device manufacturing, the width of the narrow P+ region is generally determined by the manufacturing processing capability of the equipment, and the range is generally from 0 to 3 micrometers. Here, the narrow P+ region with 1.5 micrometers width is used as an example, and FIGS. 13 to 15 respectively show the layout of the merged PiN Schottky (MPS) diode with the narrow P+ spacing set as 2 microns, 4 microns and 5 microns.

In summary, in a merged PiN Schottky (MPS) diode structure, the PN junction formed by the wide P+ region (14A) and the N-type drift region (15) can be turned on under surge current condition, forming a parallel operation mode between the PN junction and the Schottky junction, providing device with better surge current capability. The shape, size and arrangement of the wide P+ region (14A) can largely affect the electrical characteristics of the merged PiN Schottky (MPS) diode in the event of a high current surge. Therefore, it is important to study the relationship between the parameters of the wide P+ region and the device surge current capability. With a strategic design of the width and spacing of P+ region, the turn-on voltage of the PN junction can be reduced, resulting in the lower power loss and temperature rise under the current surge, therefore improving the device surge current capability.

The width and/or spacing of the P+ region (14) not only affects the surge current capability of the device, but also affects the forward voltage drop of the device under the nominal current operation, thereby influencing the conducting performance of the device. Under the nominal current condition, in which current is less than the value of the maximum steady-state operating current given in the product data sheet, because the Schottky barrier height is much lower than the PN junction built-in potential, only the Schottky junction (16) is turned on.

If the P+ region is designed with larger size and takes up too much active area, the remaining Schottky junction area will be reduced, the forward voltage drop under the nominal current conduction will increase, resulting in less competitive conducting performance. On the other hand, when the device is subjected to an abnormal surge current shock, the wider P+ region (larger P+ region area) can lower the turn-on voltage of the PN junction. Once the PN junction begins to conduct current, a large amount of minority carriers will be injected into the drift layer to reduce the electrical resistance and device voltage drop. As a result, the capability of device withstanding surge current can be enhanced. There is actually a trade-off relationship between the nominal current conduction performance and the surge current capability of the merged PiN Schottky (MPS) diode.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A semiconductor device comprising:
a substrate having a first conductivity type;
an epitaxial layer having the first conductivity type deposited on one side of the substrate;
a plurality of regions having a second conductivity type formed under a top surface of the epitaxial layer;
a first Ohmic metal patterned and deposited on top of the regions with the second conductivity type;
a Schottky contact metal deposited on top of the entire epitaxial layer to form a Schottky junction; and
a second Ohmic metal deposited on a backside of the substrate,
wherein the regions include one or more wide regions, each having a width (W) and a spacing (S) that is a distance defined between two wide regions;
and the regions also include one or more narrow regions, each having a width (W₁) and a spacing (S₁) that is a distance defined between a wide region and a narrow region, and
wherein the width (W) and spacing (S) of each wide regions, and the width (W₁) and spacing (S₁) of each narrow regions can be optimized to simultaneously obtain high surge current capability and preserve a low forward voltage drop and reverse leakage current.

2. The semiconductor device of claim 1, wherein the first conductivity type is N-type and the second conductivity type is P-type.

3. The semiconductor device of claim 1, wherein the semiconductor device is a merged PiN Schottky (MPS) diode.

4. The semiconductor device of claim 1, wherein the optimized width (W) and spacing (S) of the wide region enhances surge current capability of the semiconductor device.

5. The semiconductor device of claim 3, wherein the optimized width (W) and spacing (S) of the wide region enhances surge current capability of the merged PiN Schottky (MPS) diode.

6. The semiconductor device of claim 3, wherein the semiconductor device is a 2A 1200V merged PiN Schottky (MPS) diode with hexagonal cells, and the width of the wide region (W) ranges from 2 to 20 micrometers, while the spacing (S) of the wide region ranges from 3 to 21 micrometers.

7. The semiconductor device of claim 1, wherein the width (W₁) of the narrow region ranges from 0 to 3 micrometers.

8. The semiconductor device of claim 1, wherein a forward voltage drop of the device is reduced as the spacing (S) of the wide region increases to improve the forward conduction performance of the semiconductor device.
